(19) United States
(12) Patent Application Publication
(10) Pub. No.: US 2023/0093394 A1
(43) Pub. Date: Mar. 23, 2023

(54) DETECTION FIELDS OF VIEW

(71) Applicant: Hewlett-Packard Development Company, L.P., Spring, TX (US)

(72) Inventors: Chi So, Spring, TW (US); Alexander Wayne Clark, Spring, TX (US)

(21) Appl. No.: 17/794,941

(22) PCT Filed: Jan. 27, 2020
(86) PCT No.: PCT/US20/15172

§ 371 Date: Jul. 22, 2022

(51) Int. Cl. G01S 13/56; G01S 13/86; G01S 13/89; G06T 7/50; G06T 7/13; G01S 15/89

(52) U.S. Cl. CPC G01S 13/56; G01S 13/862; G01S 13/867; G01S 13/89; G06T 7/50; G06T 7/13; G01S 15/89

(57) ABSTRACT

An example system may include a processor and a non-transitory machine-readable storage medium storing instructions executable by the processor to generate, from data collected by a sensor, a model of an area within which a mmWave sensor is to be N utilized for presence detection; shape, based on the model, a detection field of view of the mmWave sensor to be contained within the N area; and perform the presence detection within the area utilizing the shaped detection field of view of the mmWave sensor.

### BACKGROUND

The millimeter-wave (mmWave) band of radio frequencies may include electromagnetic radiation waves with frequencies between 24 Gigahertz (GHz) and 300 GHz. The waves in the mmWave radio frequency band may have wavelengths between ten to one millimeter. The relatively small wavelengths of mmWave signals may allow the mmWave signals to penetrate and/or pass through various materials such as plastic, drywall, etc.

### BRIEF DESCRIPTION OF THE DRAWINGS

FIG. 1 illustrates an example of a system for shaping detection fields of a mmWave sensor view consistent with the present disclosure.

FIG. 2 illustrates an example of a host computing device for shaping detection fields of a mmWave sensor view consistent with the present disclosure.

FIG. 3 illustrates an example of a non-transitory machine-readable memory and processor for shaping detection fields of a mmWave sensor view consistent with the present disclosure.

FIG. 4 illustrates an example of a method for shaping detection fields of a mmWave sensor view consistent with the present disclosure.

### DETAILED DESCRIPTION

Sensors for detecting the presence and/or activities of people and objects may be integrated into various environments. For example, a sensor for detecting the presence of a living being and/or their activities may be utilized within an environment where the living being is expected to be present. In some examples, a sensor may be placed within an area that human beings may enter within.

Sensors may utilize various technologies in order to detect the presence and/or activities of people and/or objects within areas. For example, a sensor may utilize a radar-like system to detect the presence and/or activities of people and/or objects within areas. Radar systems may include systems that utilize a transmitter to transmit radio waves into the area and a receiver to receive the portion of those transmitted radio waves that are reflected off of the people and/or objects within the area and back to the receiver. The reflected radio waves collected by such sensors may be utilized to calculate information about the people and/or objects in the area, their location within the area, their actions within the area, etc.

Some examples of sensors that may utilize a radar-like system may include mmWave sensors. mmWave sensors may, for example, transmit mmWave signals in the area and utilize the reflected energy from this transmission to detect the presence, activity, gestures, location, range, velocity, angle, etc. of people and/or objects within the area.

The mmWave signal, considered to have a relatively short wavelength, may be able to provide a highly accurate radar detection within an area. For example, the mmWave signal may provide accuracy in the millimeter range. Further, the mmWave signal may have the added ability to pass through some obstructions (e.g., obstructions formed from materials such as plastic, drywall, etc.). Therefore, a mmWave sensor transceiver may be completely encased within a housing without interfering with its ability to transmit and receive mmWave signals. For example, a mmWave sensor may be utilized to deliver and receive mmWave signals even when fully encased within a body such as a plastic body of the sensor and/or a computing device that the sensor is integrated within. That is, the mmWave sensor may be able to “see” through a plastic body of a device as well as other obstructions in and around the area that it is monitoring.

However, the ability of mmWave signals to pass through obstructions may contribute to false positives (e.g., detections of people and/or objects within an area where there are no actual people and/or objects within the area). For example, an area being monitored by a mmWave sensor may include an area of interest. An area of interest may be an area within which the mmWave sensor is to detect the presence and/or activities of people and objects. As such, the detection of the presence and/or activities of people and objects outside of the area of interest by the mmWave sensor while monitoring the area of interest may result in a false positive.

The mmWave sensor may have a detection field of view. The detection field of view of the mmWave sensor may include the entire area that the mmWave sensor can “see” or sense within. For example, the detection field of view of the mmWave sensor may include an entire area within which the mmWave signals transmitted from the mmWave sensor may reach and/or the entire area from which reflected mmWave signals may be received and/or detected by the mmWave sensor.

A detection field of view for a mmWave sensor may be different from the area of interest. For example, the detection field of view for a mmWave sensor may not be the same size as, fit within, have the same geometry as, etc. the area of interest. For example, the area of interest may be defined by abstract boundaries and/or physical obstructions. However, the detection field of view may not precisely overlap with such boundaries or physical obstructions. In some examples, the detection field of view of the mmWave sensor may include an area smaller than or larger than the area of interest.

For example, the area of interest may include a room and the room may be defined by walls, doors, windows, dividers, architectural features, etc. In some examples, the area may include a room such as a conferencing room, although examples are not so limited. The mmWave sensor, given that its mmWave signals can pass through various materials from which the walls, doors, windows, dividers, architectural features, etc. are constructed, may transmit mmWave signals through the materials and outside of the room or area of interest.

In addition, the mmWave sensor may be able to detect mmWave signals returned and/or received from outside of such a room or area of interest. For example, the mmWave signal may receive mmWave signals reflected off of detectable people and/or objects outside of the area of interest. The mmWave signals may be reflected back through the room boundary materials and back into the area of interest where they may be received by the mmWave sensors. As such, the mmWave sensors may detect the presence and/or activities of people and objects outside of the room or area of interest, which may not be distinguished from the presence and/or activities of people inside the room or area of interest. The result may be an erroneous determination that the presence and/or activities of people and objects outside the room are detected from within the area of interest.

In some examples, a mmWave sensor may be communicatively coupled to a machine or computing device. The communicative coupling of the mmWave sensor to the machine or computing device may allow for the mmWave sensor and/or its detections to be utilized in actuating and/or adjusting the activity of the machine or computing device. For example, the activity of the machine or computing device may be modified based on the presence and/or activities of people and objects within the area of interest as detected by the mmWave sensor. In such examples, false positive determinations may lead to erroneous, superfluous, damaging, resource consuming, etc. actuations and/or adjustments of the activity of the machine responsive to the detection of the presence and/or activities of people and objects that are not actually within the area of interest.

In contrast, examples consistent with the present disclosure may include a mechanism to shape a detection field of view of a mmWave sensor to an area of interest. Examples consistent with the present disclosure may provide an automated shaping of the detection field utilizing sensors within the area to model the area and shape the detection field of view accordingly. For example, examples consistent with the present disclosure may include a system including a processor and a non-transitory machine-readable storage medium to store instructions executable by the processor to generate, from data collected by a sensor, a model of an area within which a mmWave sensor is to be utilized for presence detection; shape, based on the model, a detection field of view of the mmWave sensor to be contained within the area; and perform the presence detection within the area utilizing the shaped detection field of view of the mmWave sensor.

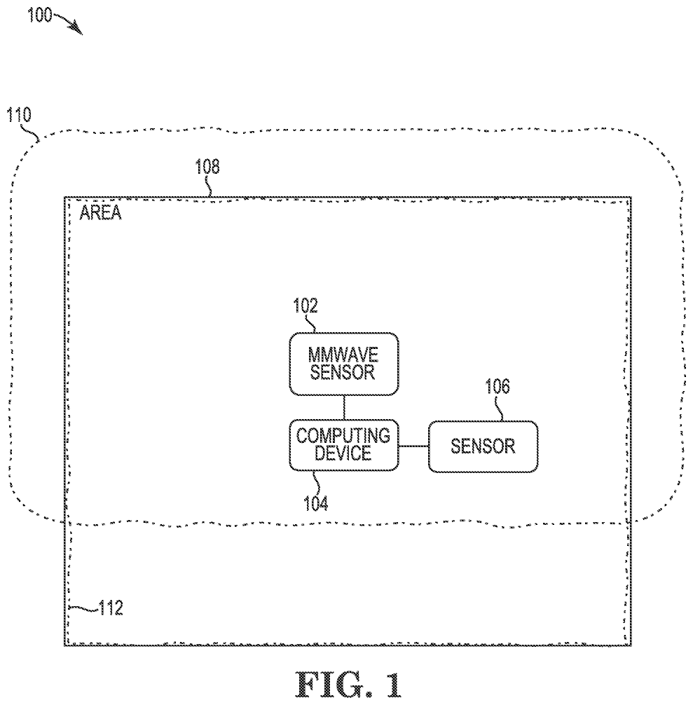

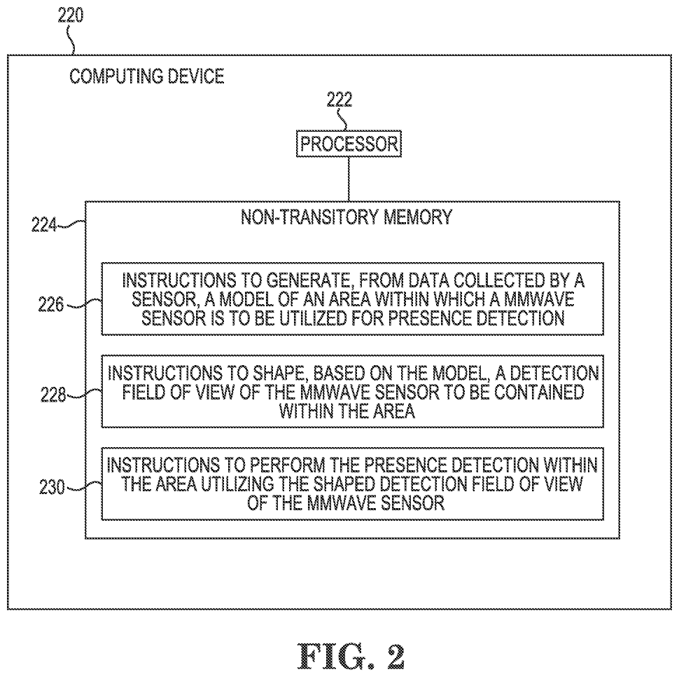

FIG. 1 illustrates an example of a system 100 for shaping detection fields of a mmWave sensor view consistent with the present disclosure. The described components and/or operations of the system 100 may include and/or be interchanged with the described components and/or operations described in relation to FIG. 2-FIG. 4.

The system 100 may include a mmWave sensor 102. The mmWave sensor 102 may include a transceiver that may utilize an antenna in the transmission and/or reception of mmWave signals. The antenna may include a single antenna and/or a plurality of antennas. For example, the antenna may include an antenna array to transmit mmWave signals in a pattern. For example, the antenna may include an antenna array providing mmWave signal transmission and/or reception coverage three hundred sixty degrees about the mmWave sensor 102 and/or the antenna array. For example, the mmWave sensor 102 may include an antenna for emitting a mmWave signal into the area 108 where the mmWave sensor 102 is physically located. The mmWave sensor 102 and/or its antenna may transmit the mmWave signals three hundred sixty degrees about the mmWave sensor 102 into the area 108.

The mmWave sensor 102 and/or its antenna may be enclosed within a housing. For example, the mmWave sensor 102 and/or its antenna may be enclosed within a distinct mmWave sensor housing and/or be enclosed with the body of a computing device, such as computing device 104, within the area 108. As such, the mmWave signals transmitted by the mmWave sensor 102 may pass through the walls of their enclosure and into the area 108. That is, the housing of the mmWave sensor 102 and/or its antenna may not include additional apertures or openings to accommodate the transmission and/or reception of mmWave signals as these signals may pass directly through the materials from which these housings are created. As such, mmWave sensor 102 housings may have a clean, sleek, and/or minimalist aesthetic since the housing may not include geometric interruptions to accommodate signal transmissions.

The mmWave sensor 102 may detect the presence and/or activities of people and objects within a detection field of view (e.g., 110, 112). The detections may be based on the mmWave signals reflected off of people and/or objects in the detection field of view and back to the mmWave sensor's antenna. The mmWave sensor 102 may be integrated with additional systems (e.g., environment control, machine control, security, etc.). For example, the detections by the mmWave sensor 102 may be utilized as triggering inputs for other systems. For example, a mmWave sensor 102 may detect the presence and/or activities of people and/or objects within a detection field of view in order to trigger a response by a computing device, such as computing device 104. For example, the mmWave sensor 102 may adjust a functionality of a computing device in an area 108 in response to detecting the presence and/or activities of people and objects within its detection field of view.

The mmWave sensor 102 may have an initial detection field of view 110. The initial detection field of view 110 may include a physical area within which the mmWave sensor 102 can “see” or monitor for the purposes of performing its detection operations and/or outside of which the mmWave sensor 102 cannot “see” or monitor for the purposes of performing its detection operations. For example, the initial detection field of view 110 of the mmWave sensor 102 may include a physical area within which mmWave signals are transmitted by the mmWave sensor 102 and/or within which mmWave signals reflected from a detectable object within the physical area are received. Further, the initial detection field of view 110 of the mmWave sensor 102 may include a physical area outside of which mmWave signals are not transmitted by the mmWave and/or outside of which mmWave signals reflected from detectable objects are not detected or are not acknowledged. That is, the initial detection field of view 110 may include boundaries that may represent artificial and/or functional limits of detection by the mmWave sensor 102.

The initial detection field of view 110 of the mmWave sensor 102 may have a geometry defined by a default or preset setting. For example, the initial detection field of view 110 of the mmWave sensor 102 may result from operating the mmWave sensor 102 according to settings (e.g., mmWave signal transmission power settings, signal processing protocols, etc.). These settings may be set by a manufacturer and shipped with the mmWave sensor 102 prior to its deployment in a particular area 108. In other examples, the initial detection field of view 110 may have a geometry defined by a prior setting. For example, the initial field of view 110 may have a geometry defined by a setting resulting from a previous shaping of the detection field of the mmWave sensor 102 to the same or to a different area.

In some examples, the initial detection field of view 110 may not align with an area 108. That is, the boundaries of the initial detection field of view 110 may not be aligned with and/or correspondingly limit the initial detection field of view 110 to within the boundaries of the area 108. The area 108 may include a physical space where the mmWave sensor 102 is to be utilized for presence detection. The area 108 may have boundaries. The boundaries may be physical obstructions and/or abstract bounds that define the geometry of the area 108 within the boundaries. For example, the area 108 may include a room such as a conference room. The boundaries of the room 108 may include physical obstructions such as doors, walls, windows, floors, ceilings, architectural features, dividers, etc. that encompass and/or define the geometry of the area 108 of the room.

The mmWave sensor 102 may be located within the area 108. That is, the mmWave sensor 102 may be physically positioned at a location within the area 108. For example, a computing device that includes the mmWave sensor 102 incorporated therein may be placed within the area 108.

The mmWave sensor 102 may be positioned within the area 108 in order to perform detection operations for the area 108. A detection operation may include utilizing the mmWave sensor to detect the presence and/or activities of people and/or objects within the area 108. For example, the mmWave sensor 102 may be positioned within the area 108 in order to detect the presence and/or activities of people and/or objects within the area 108 in order to trigger a response by a computing device, such as computing device 104.

However, as described above, the initial detection field of view 110 may not align with and/or correspond to the bounds of an area 108. For example, portions of the initial detection field of view 110 may extend outside the boundaries of the area 108. Further, the initial detection field of view 110 may not cover some portions of the area 108 at all. As a result, if the mmWave sensor 102 were operated with its initial detection field of view 110 within the area 108, then false positive detection events resulting from detections from outside of the area 108 but within the initial detection field of view 110 may be produced. Additionally, the mmWave sensor 102 could produce false negatives by missing detection events that are detectable within the area 108 but are outside of the initial detection field of view 110.

The system 100 may include a sensor 106. The sensor 106 may include a sensor 106 that is located within the area 108. The sensor 106 may be positioned within the area 106 and/or may be communicatively coupled to or may be an integrated component of a computing device, such as computing device 104, located in the area 108. The sensor 106 may include a sensor to sense data about the environment and/or characteristics of the area 108 within which it is located. For example, the sensor 106 may include a device which detects and/or measures physical properties of the area 108. For example the sensor 106 may capture data regarding the dimensions, layout, geometric features, length, width, height, appearance, boundary placements, etc. for the room that the sensor 106, the mmWave sensor 102, and/or the computing device 104 are positioned within.

In some examples, the sensor 106 may include an audio system. For example, the senor 106 may include a speaker and/or a microphone for audio mapping of the area 108. For example, the speaker may be utilized to emit an audio ping into the area 108. In some examples, the speaker may be utilized to emit an ultrasonic audio ping.

The microphone may be utilized to receive the results of the above-described ping. For example, the microphone may detect portions of that ping that are reflected back to the microphone from the area 108. For example, the ultrasonic ping may be emitted from the speaker, travel out into the area 108, and reflect off of the boundaries of the area 108 and back toward the speaker and/or microphone where it is captured. By analyzing the echo of the propagated ultrasonic ping, measurements and/or geometric features of the area 108 may be determined.

In other examples, the sensor 106 may include a camera positioned within the area 108. The camera may capture images of the area 108. In some examples, the images captured by the camera may include data that may be utilized to determine measurements and/or geometric features of the area 108.

The system 100 may include a computing device 104. The computing device 104 may be distinct from and/or communicatively coupled to mmWave sensor 102 and/or the sensor 106. Alternatively, the computing device 104 may be incorporated with the mmWave sensor 102 and/or the sensor 106. The computing device 104 may include a laptop computer, desktop computer, a tablet computer, smartphone, smart device, Internet of things (IOT) device, smart appliance, a wearable smart device, a monitor, conferencing equipment, a smart board, a projector, a speaker phone, an access point, building systems controller, etc. The computing device 104 may collect data from the mmWave sensor 102 and/or the sensor 106, analyze and/or manipulate the data, and/or control the operation of the mmWave sensor 102 and/or the sensor 106.

The computing device 104 may cause the sensor 106 to utilize its sensing functionality to collect data about the area 108. The computing device 104 may generate, from the data collected by the sensor 106, a model of the area 108 within which the mmWave sensor 102 is to be utilized for presence detection. That is, the data collected by the sensor 106 may be analyzed and/or manipulated in order to produce a map of, for example, a room within which a user will utilize the mmWave sensor 102 to detect the presence and/or activities of people and/or objects.

In examples where the area 108 is a conferencing room, the sensor 106 may be positioned in the conferencing area 108 and may be activated to sense data about the conferencing room. The data collected by the sensor 106 may be analyzed and/or manipulated by the computing device 104 to generate a model or mapping of the dimensions, layout, geometric features, length, width, height, appearance, boundary placements, etc. of the conference room. The model may include a map characterizing a geometry of the confines of the conference room. That is, the model may identify the location, dimensions, layout, geometric features, length, width, height, appearance, etc. of the boundaries (e.g., walls, doors, windows, ceilings, floors, dividers, architectural features, etc.) that define and/or encompass the interior of the conference room area 108.

The model, generated and/or refined from the data collected by a sensor, may be utilized to shape a detection field of view (e.g., shaped detection field of view 112) for the mmWave sensor 102 to the area 108. For example, the computing device 104 may utilize the data collected from the sensor 106 and/or the model of the area 108 generated from the data collected from the sensor 106 to generate an updated detection field of view for the mmWave sensor 102. In some examples, shaping the detection field of view may include producing a shaped detection field of view 112 to be utilized by the mmWave sensor 102 in order to monitor the area 108. Producing a shaped detection field of view 112 may include defining, redefining, and/or manipulating the artificial and/or functional boundaries of a mmWave sensor's 102 detection field of view. In some examples, shaping the detection field of view may include reshaping or modifying the detection field of view of the mmWave sensor 102 from the initial detection field of view 110 to the shaped detection field of view 112.

The shaped detection field of view 112 for the mmWave sensor 102 may be generated from the model such that the shaped detection field of view 112 may be contained within the area 108. For example, the shaped detection field of view 112 for the mmWave sensor 102 may be generated from the model such that it fills and/or substantially occupies the entire area 108. The shaped detection field of view 112 for the mmWave sensor 102 may be generated from the model such that its boundaries do not extend outside of the boundaries of the area 108. The shaped detection field of view 112 for the mmWave sensor 102 may be generated from the model such that its boundaries substantially align with the boundaries of the area 108. For example, shaping the detection field of view 112 of the mmWave sensor 102 may include adjusting the boundaries of the detection area for the mmWave sensor 102 such that they are matched to and/or aligned with the boundaries of the area 108. Therefore, portions of the initial detection field of view 110 that may extend outside the boundaries of the area 108 may be shaped to fit within those boundaries and/or the initial detection field of view 110 may have its boundaries expanded in other areas to cover portions of the area 108 not previously covered by the initial detection field of view 110.

As described above, the mmWave sensor 102 may be located within and/or around the area 108. Further, shaping the detection field of view of the mmWave sensor 102 to the shaped detection field of view 112 may include modifying (increasing, decreasing, moving, adjusting, adding, removing, recontouring, etc.) the position of the boundaries of the initial detection field of view 110 for the mmWave sensor 102 to the area 108. The modification to the position of the boundaries may be achieved by modifying (increasing, decreasing, pulsing, changing a delivery pattern, removing, etc.) the power delivered to and/or utilized by an antenna of the mmWave sensor 102. For example, by modifying the power supplied to a transmitting antenna of the mmWave sensor 102 to transmit a mmWave signal a boundary position may be modified by boosting and/or reducing the power of the mmWave signals its transmitting. For example, the boundary of the initial detection field of view 110 for the mmWave sensor 102 may be expanded or moved out further from the mmWave sensor 102 by increasing the power supplied to the transmit antenna. Increasing the power supplied to the transmit antenna may, for example, result in a boost to the power of the mmWave being transmitted and a corresponding increase in its range.

Conversely, the boundary of the initial detection field of view 110 for the mmWave sensor 102 may be decreased or moved inward closer to the mmWave sensor 102 by decreasing the power supplied to the transmit antenna. For example, decreasing the power supplied to the transmit antenna may result in a reduction to the power of the mmWave being transmitted and a corresponding decrease in its range.

Additionally, a boundary of the initial detection field of view 110 for the mmWave sensor 102 may be added and/or have its contour reshaped in an additive manner by introducing power to the transmit antenna. That is, by powering a transmit antenna that was not previously powered, a mmWave signal may be transmitted into a previously uncovered portion of the area 108. Conversely, the boundary of the initial detection field of view 110 for the mmWave sensor 102 may be removed by removing or interrupting the power to the transmit antenna.

Again, as mentioned above, the mmWave sensor 102 may include an array of antennas that provide, for example, three hundred sixty-degree mmWave signal coverage about the mmWave sensor 102. As such, the boundary of the initial detection field of view 110 for the mmWave sensor 102 may be modified in various directions by modifying particular ones of the array of transmit antennas corresponding to the various directions. That is, by selectively modifying power supplied to particular antennas of the array of transmit antennas, the boundaries of the initial detection field of view 110 for the mmWave sensor 102 may be precisely contoured to the boundaries of the area 108 regardless of its particular geometry. That is, increasing the power supplied to an array collectively may result in equidistant expansion of the boundaries of the detection field of view about the entire three hundred sixty-degree mmWave signal coverage. However, selectively increasing the power supplied to individual antennas of an array may allow for directionality in boundary manipulations which may be differing and/or unequal about the entire three hundred sixty-degree mmWave signal coverage.

Additionally, the shaping of the detection field of view for the mmWave sensor 102 may be accomplished through data/signal processing mechanisms. For example, the modifications to the position of the boundaries of the initial detection field of view 110 for the mmWave sensor 102 may be achieved through data processing mechanisms that manipulate how the data received by the mmWave sensor 102 is processed in order to exclude and/or included certain detections. For example, the position of the boundaries of the initial detection field of view 110 for the mmWave sensor 102 may be modified by applying various electronic filters that prevent the mmWave sensor 102 from receiving and/or considering as a detection a reflected mmWave signal that may have been reflected back from a position outside of the area 108. Such electronic filtering mechanisms may utilize gain adjustments, signal timing parameters, signal patterns, etc. to identify the reflected mmWave signals that may have been reflected back from a position outside of the area 108 and that, as a result, are to be filtered out. In some examples, the computing device 104 may apply such filters by analyzing and/or manipulating the data generated from detections by the mmWave sensor 102 according to electronic filtering instructions.

Utilizing the examples described above, a shaped detection field of view 112 may be created by modifying the position of the boundaries of the initial detection field of view 110. The boundaries of the shaped detection field of view 112 may be contoured to and/or be forced into containment within the area 108. As such, the mmWave sensor 102 may have its detection field of view customized to each area 108 within which it is to perform presence detection operations. That is, regardless of the room that the mmWave sensor 102 is placed within to perform presence detection operations and regardless of its previously configured detection field of view, the mmWave sensor 102 may be automatically adapted to the room without involving manual configuration by a user.

The mmWave sensor 102 may, following the production of the shaped detection field of view 112, be utilized to perform an assigned presence detection operation within the area utilizing the shaped detection field of view 112. Detection operations may include detecting a living thing within or entering the area 108, detecting an object within or entering the area 108, motion detection within or entering the area 108, counting people or objects within or entering the area 108, gesture identification within the area 108, eye tracking or other privacy tracking measurements within the area 108, etc. The mmWave sensor 102 may monitor the area 108 via the presence detection operations without the use of the sensor 106 and/or without the use of data collected by the sensor 106. That is, the sensor 106 may not be utilized in the performance of the detection operations by the mmWave sensor 106.

In some examples, the sensor 106 may be disabled and/or access by the computing device 104 to the data being collected by the sensor 106 may be discontinued following the generation of the model. For example, as described above, the sensor 106 may include a speaker and/or a microphone. The computing device 104 may cause the speaker to generate an ultrasonic ping to be reflected back to the microphone to measure the area 108. The computing device 104 may cause the microphone to detect the reflected waves to generate the model. However, once the model of the area 108 is generated, the computing device 104 may disable the speaker and/or microphone and/or stop analyzing data from the speaker and/or microphone. The speaker and/or microphone may be utilized for other purposes following generating the model. For example, the speaker and/or microphone may be utilized for delivering and/or receiving conferencing audio.

Additionally, the sensor 106 may include a camera. The camera may be utilized to capture image data to measure the area 108. The computing device 104 may cause the camera to capture images of the area 108. The computing device 104 may, for example, access a feed of images collected by the camera to collect the images of the area 108. However, once the model of the area 108 is generated, the computing device 104 may disable the camera and/or stop analyzing data from the camera. The camera may be utilized for other purposes following generating the model. For example, the camera may be utilized for capturing and/or communicating images, such as for a teleconference.

Some users may have privacy concerns surrounding the presence of sensors 106, such as cameras and/or microphones, within their environments. By discontinuing data collection by the sensor 106 and/or refraining from utilizing the sensor 106 for presence detection operations, these privacy concerns may be assuaged. For example, a user may be more comfortable with a camera or microphone being present in the area 108 and/or utilized momentarily for modeling the area 108 when the camera or microphone may be disabled or be access controlled thereafter.

The mmWave sensor 102 may trigger an adjustment to a computing device (e.g., computing device 104) or other device responsive to detecting the presence and/or activities of people and/or objects within the area 108. For example, if the mmWave sensor 102 detects the presence and/or activities of people and/or objects within the shaped detection field of view 112 shaped to the area 108, a computer setting adjustment or action may be triggered to a device in the area 108. In some examples, a light may be turned on in the area 108, a monitor may be turned on in the area 108, a projector may be booted up in the area 108, a smartboard may be booted up in the area 108, a thermostat may be adjusted in the area 108, blinds may be raised in the area 108, etc. in response to the mmWave sensor 102 detecting the presence and/or activities of people and/or objects within the shaped detection field of view 112. As such, by shaping the detection field of view of the mmWave sensor 102 to the area 108, examples consistent with the present disclosure may prevent superfluous resource consumption and save wear and tear on a computing device by avoiding false positive activations caused by detecting the presence and/or activities of people and/or objects outside the area 108. Further, the shaped detection field of view 112 may prevent missed presence and/or activity detections within the area 108 by insuring full coverage within the area 108.

FIG. 2 illustrates an example of a computing device 220 for shaping detection fields of view of a mmWave sensor consistent with the present disclosure. The described components and/or operations described with respect to the computing device 220 may include and/or be interchanged with the described components and/or operations described in relation to FIG. 1 and FIG. 3-FIG. 4.

The computing device 220 may include a laptop computer, desktop computer, a tablet computer, smartphone, smart device, Internet of things (IOT) device, smart appliance, a wearable smart device, a monitor, conferencing equipment, a smart board, a projector, a speaker phone, an access point, building systems controller, etc. The computing device 220 may include a processor 222 and/or a non-transitory memory 224. The non-transitory memory 224 may include instructions (e.g., 226, 228, 230, etc.) that, when executed by the processor 222, cause the computing device 220 to perform various operations described herein. While the computing device 220 is illustrated as a single component, it is contemplated that the computing device 220 may be distributed among and/or inclusive of a plurality of such components.

The computing device 220 may include instructions 226 executable by the processor 222 to generate, from data collected by a sensor, a model of an area within which a mmWave sensor is to be utilized for presence detection. The area may include a room. For example, the area may include an office or conferencing area.

The sensor may include a microphone positioned within the room. As such, the data collected by the sensor may include sound waves detected by the microphone resulting from an ultrasonic ping emitted from an audio speaker. The model of the area may include an ultrasonic audio mapping of the room generated from the sound waves detected by the microphone. The model may include a geometry of the confines of the room.

In some examples, the sensor may include a camera. The camera may be positioned within the area. In some examples, the camera may include a red green blue (RGB) camera, an infrared (IR) camera, etc. The camera may include a two-dimensional camera for capturing two-dimensional images and/or a three-dimensional camera for capturing three-dimensional images.

The computing device 220 may include instructions 228 executable by the processor 222 to shape a detection field of view of the mmWave sensor. The detection field of view may be shaped based on the above-described model. Shaping the detection field of view of the mmWave sensor may include shaping the detection field of view of the mmWave sensor to be contained within the area. For example, the detection field of view of the mmWave sensor may be shaped by expanding, contracting, adding, removing, etc. the boundaries of the detection field of view such that they align with the boundaries of the area as determined in the above-described model.

The computing device 220 may include instructions 230 executable by the processor 222 to perform the presence detection within the area utilizing the mmWave sensor. The shaped detection field of view of the mmWave sensor may be utilized in performing the presence detection operations. For example, the mmWave sensor may monitor the area for living things by monitoring within the shaped detection field of view.

During the presence detection operation, the sensor may not be utilized for presence detection. Instead, data collection by the sensor may be discontinued following generation of the model. Thereafter, the sensor may not be utilized for the presence detection operation. Instead, the presence detection may be accomplished utilizing just the mmWave sensor. For example, the generation of the model of the area and the shaping of the detection field of view may be part of a configuration process. For example, a configuration operation may be initiated which configures the mmWave sensor to a room responsive to a prompt (e.g., a user indication, a detected change in position of the mmWave sensor, detected placement within a room, etc.). The configuration change operation may include the generation of the model and the corresponding shaping of the detection field of view. However, after the completion of the configuration change operation, the sensors may be disabled and/or access to their data for the purposes of configuring the detection field of view for the mmWave sensor may be discontinued.

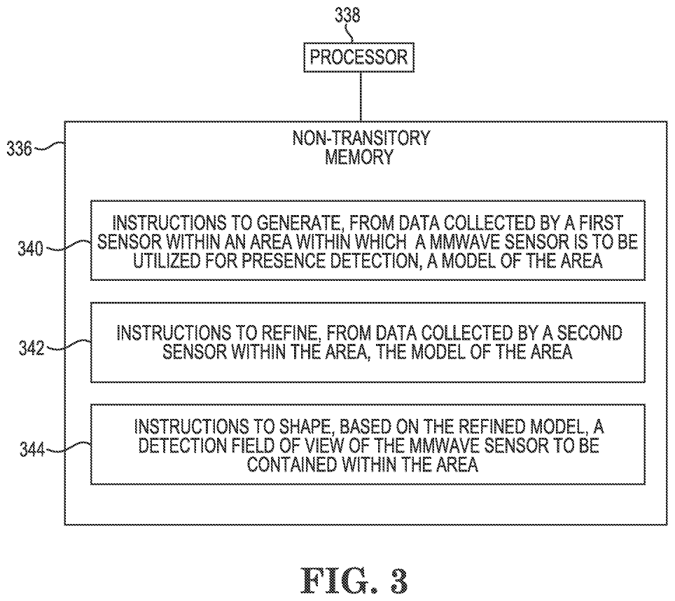

FIG. 3 illustrates an example of a non-transitory machine-readable memory 336 and processor 338 for shaping detection fields of view of a mmWave sensor consistent with the present disclosure. A memory resource, such as the non-transitory machine-readable memory 336, may be utilized to store instructions (e.g., 340, 342, 344, etc.). The instructions may be executed by the processor 338 to perform the operations as described herein. The operations are not limited to a particular example described herein and may include and/or be interchanged with the described components and/or operations described in relation to FIG. 1-FIG. 2 and FIG. 4.

The non-transitory memory 336 may store instructions 340 executable by the processor 338 to generate a model of an area. The area may include a room or other area within which a mmWave sensor is to be utilized for presence detection. The model of the area may be generated from data collected by the first sensor within the area. The model may include a map of the area.

In some examples, the first sensor may include a speaker and/or a microphone for mapping the area utilizing sound. For example, the first sensor may include a speaker to emit an ultrasonic ping which will be reflected back to the microphone off of people and/or objects in the area. In such examples, the model may include a sound map of the area. That is, the model may include a map of the area created from the reflected sound detected at the microphone sensor.

The non-transitory memory 336 may store instructions 342 executable by the processor 338 to refine the model of the area. Refining the model may include modifying the model. For example, refining the model may include adding data to, subtracting data from, revising data, improving data, etc. to improve the accuracy of the model with respect to the area.

The model of the area may be refined with data collected by a second sensor within the area. The data collected from the second sensor may be utilized to supplement and/or modify the model generated from the data collected by the first sensor. Each time additional sensor data from additional sensors in the area is added to the model, the model's fidelity to the actual area may be improved. In some examples, the data collected by the second sensor may be superimposed on to the model generated from the data collected by the first sensor. For example, the data collected by the second sensor may be superimposed onto the sound map of the area.

In some examples, the second sensor may include a camera. For example, the second sensor may include a depth camera. The depth camera may collect data including the distance to various living things, objects, boundaries, etc. within the area. The distances may be superimposed onto the sound map of the area in order to increase its fidelity.

In some examples, the second sensor may include an RGB camera. The RGB camera may collect images of the area that may be processed with an edge detection technique in order to identify edges in the area. The edge data may be superimposed onto the sound map of the area in order to increase its fidelity.

By combining data from the first and second sensors, a more detailed and accurate mapping of the area may be achieved. The more accurate the model of the room, the more accurate the shaping of the detection field of the mmWave sensor may be with respect to providing coverage over the entire area without monitoring spaces outside of the area. Examples consistent with the present disclosure may not be limited to any particular amount of sensors whose data may be combined to refine, improve, increase the fidelity of, and/or generate a model of the area.

The non-transitory memory 336 may store instructions 344 executable by the processor 338 to shape the detection field of view of the mmWave sensor to be contained and/or confined within the area. Shaping the detection field of view may include modifying the physical proximity of the boundaries of the detection field of view of the mmWave sensor so that they align with boundaries of the area where the mmWave sensor will be monitoring. The particular modifications to be performed to the detection field of view may be determined based on the refined model of the area. That is, the refined model of the area may be utilized to determine the confines of and/or boundaries of an area such as a room where the mmWave sensor will be positioned and operated to perform presence detection operations.

As such, shaping the detection field of view of the mmWave sensor may include adjusting the detection field of view of the mmWave sensor such that the entire area to be monitored is within the detection field of view of the mmWave sensor. Additionally, shaping the detection field of view of the mmWave sensor may include adjusting the detection field of view of the mmWave sensor such that presence detection data from outside of the area is excluded in presence detection operations. For example, the power supplied to a portion of an antenna array of the mmWave sensor may be modulated in order to modulate the strength and/or range of the mmWave signals transmitted therefrom. The power supply may be modulated such that the mmWave signals do not escape to and/or reflect from outside of the area. In other examples, software filters may be applied to data detected by the mmWave sensor in order to filter out mmWave signals reflected back to the mmWave sensor from outside of the area.

The mmWave sensor may be operated within the area to perform presence detection operations. For example, the mmWave sensor, independently from and/or without the assistance of the first and second sensors, may be utilized within the area to identify the presence of various activities, people, objects, etc. within the area. The mmWave sensor may perform the monitoring of the area and/or the presence detection operations by limiting its monitored area to the shaped detection field of view. Since the shaped detection field of view was customized to be contained within the area, the mmWave sensor may monitor the entire area and/or to exclude data from outside of the area as a result of the correspondence.

The mmWave sensor may be utilized as part of an environment automation system. For example, detection events by the mmWave sensor from within the shaped detection field of view may be utilized to trigger automated changes to devices within and/or supporting the area. For example, if the area is a conference room, a detection event by the mmWave sensor may be utilized to trigger a series of actions by devices within and/or supporting the conference room to prepare the conferencing room to host a meeting. Additionally, detection events by the mmWave sensor from within the shaped detection field of view may be utilized to trigger automated prompts that may prompt a user to indicate whether they would like the system to trigger automated changes to devices within and/or supporting the area.

In some examples, a portion of the area where the detection event by the mmWave sensor was sensed may be utilized to determine whether to trigger an automated prompt verses to trigger automated changes to devices within and/or supporting the area. For example, based on the refined model, the boundaries of the area may be precisely and accurately defined. Accordingly, the mmWave sensor may be adapted to detect whether a detection event occurs at or near an area boundary.

As such, when a detection event occurs within the shaped detection field of view at or near the area boundaries indicated in the model, an automated prompts prompting a user to indicate whether they would like the system to trigger automated changes to devices within and/or supporting the area may be triggered. Conversely, if the detection event occurs within and/or proceeds within the shaped detection field of view a distance away from the area boundaries indicated in the model, then the series of actions by devices within and/or supporting the area that prepare the conferencing room to host a meeting may be triggered without prompting a user indication.

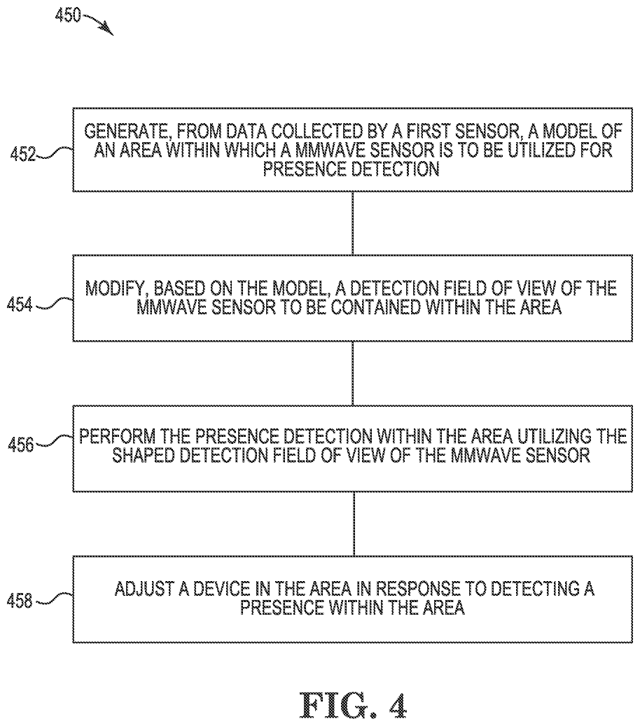

FIG. 4 illustrates an example of a method 450 for shaping detection fields of view of a mmWave sensor consistent with the present disclosure. The described components and/or operations of method 450 may include and/or be interchanged with the described components and/or operations described in relation to FIG. 1-FIG. 3.

At 452, the method 450 may include collecting data from a first sensor. The first sensor may include a sensor positioned within an area within which a mmWave sensor is to be utilized for presence detection. The first sensor may include any type of sensor that may be utilized to capture data characterizing the area. For example, the first sensor may include a sensor that may capture data regarding the dimensions, layout, geometric features, length, width, height, appearance, boundary placements, etc. for the area.

The first sensor may include a sensor other than a mmWave sensor. The first sensor may include a speaker/microphone combination capable of collecting ultrasonic mapping data about the area. Additionally, the first sensor may include a camera for collecting images and/or other data about the area.

The data collected by the first sensor may be utilized to generate a model of the area within which the mmWave sensor is to be utilized for presence detection. For example, a map including dimensions, angles, contours, distances, volumes, obstruction locations, boundary locations, etc. for the area may be created from the data collected by the first sensor. The map may be refined and/or its fidelity improved by incorporating data from additional sensors.

The area may include a structure, such as a room, where the mmWave sensor will be utilized for presence detection. The area may be a same area where other computing devices are located that may be utilized to support activities within the area (e.g., conducting a video and/or audio conference, conducting a teleconference, conducting a presentation, holding a meeting, performing a task, etc.).

The mmWave sensor may be communicatively coupled to the other computing device and/or a controller for the other computing devices. As such, presence detection events detected by the mmWave sensor may be utilized as triggering activities to trigger adjustments to the other computing devices within the area via the communicative couplings.

At 454, the method 450 may include modifying a detection field of the mmWave sensor. The detection field of the mmWave sensor may include the field of view within which the mmWave sensor may monitor for and detect the presence of living things, objects, actions, etc. The detection field of the mmWave sensor may include the field of view outside of which the mmWave sensor may be unable to and/or be prohibited from monitoring and detecting the presence of living things, objects, actions, etc. The dimensions of the detection field of a mmWave sensor may initially be the result of factory settings or previous settings applied to the mmWave sensor.

Modifying the detection field of view may include adjusting the dimensions of the detection field of view for the mmWave sensor. The modifications to the detection field of view may be based on the model of the area generated from the sensor data. The modifications to the detection field of view may include modifications that cause the detection field of view to be contained and/or confined within the area. For example, the modifications to the detection field of view may include modifications that cause the detection field of view to fill the volume of the area out to the boundaries of the area and/or modifications that restrict the detection field of view to at and/or within the boundaries of the area.

In some examples, modifying the detection field of view may include adjusting a wave strength of an electromagnetic wave emitted from the mmWave sensor. For example, the wave strength of the mmWave signal emitted from the mmWave sensor may be adjusted by corresponding adjustments to the amount of power provided to an antenna of an array of antennas of the mmWave sensor where the mmWave signal is being emitted. By providing the antenna more power during emission a more powerful mmWave signal may be emitted which may travel relatively further distances from the antenna. Alternatively, by providing the antenna less power during emission a less powerful mmWave signal may be emitted which may travel relatively lesser distances from the antenna. Therefore, by differentially adjusting the power provided to each antenna of an array of antennas, the detection field of view of the mmWave signal may be contoured to the area defined in the model.

Further, as described above, modifying the detection field of view of the mmWave sensor may include applying filters to the data collected by the mmWave sensor. For example, a filter may be applied to the data collected by the mmWave sensor to electronically filters out and/or discards mmWave signal detections that occur outside of the area defined by the model.

At 456, the method 450 may include performing the presence detection within the area utilizing the shaped detection field of view of the mmWave sensor. For example, the mmWave sensor may be activated to monitor for the presence of people, objects, and/or actions within its modified detection field of view. Since the modified detection field of view is customized to the boundaries of the area that the mmWave sensor is housed within, the modified detection field of view may be customized to the particular area.

At 458, the method 450 may include adjusting a device in the area in response to detecting the presence of a person, object, action, etc. within the area. For example, if the mmWave sensor detects a person, object, action, etc. within its modified detection field of view, contoured to the area, then an adjustment to devices within the area may be triggered.

Therefore, the mmWave sensor may act as a customized proximity sensor for a device or group devices within an area. As such, integrating the mmWave sensor into a multifunction computing device and/or a system of devices in an area may provide for automated responses to proximity among the controlled devices. Therefore, resources may be conserved by triggering device responses responsive to proximity rather than leaving the devices in the responsive mode all the time.

Additionally, the millimeter range accuracy provided by the mmWave sensor may provide high resolution monitoring of the area. However, the tendency of mmWave signals to over penetrate and provide readings from outside of the area may be ameliorated by generating the model of the area and/or shaping the detection field of view to the model.

In the foregoing detailed description of the disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the present disclosure. Further, as used herein, “a plurality of” an element and/or feature can refer to more than one of such elements and/or features.

The figures herein follow a numbering convention in which the first digit corresponds to the drawing figure number and the remaining digits identify an element or component in the drawing. Elements shown in the various figures herein may be capable of being added, exchanged, and/or eliminated so as to provide a number of additional examples of the disclosure. In addition, the proportion and the relative scale of the elements provided in the figures are intended to illustrate the examples of the disclosure and should not be taken in a limiting sense.

What is claimed:

1. A system, comprising:
a processor; and
a non-transitory machine-readable storage medium to store instructions executable by the processor to:
generate, from data collected by a sensor, a model of an area within which a mmWave sensor is to be utilized for presence detection;
shape, based on the model, a detection field of view of the mmWave sensor to be contained within the area; and
perform the presence detection within the area utilizing the shaped detection field of view of the mmWave sensor.

2. The system of claim 1, wherein the sensor includes a microphone positioned within the area.

3. The system of claim 2, wherein the model of the area includes an ultrasonic mapping of the area, and wherein the data collected by the sensor includes sound waves detected by the microphone from an ultrasonic ping emitted from an audio speaker.

4. The system of claim 1, wherein the area includes a room and the model includes a geometry of confines of the room.

5. The system of claim 1, wherein the sensor includes a camera positioned within the area.

6. The system of claim 5, including instructions executable by the processor to discontinue data collection by the camera following generation of the model and refrain from utilization of the camera for the presence detection.

7. A non-transitory machine-readable storage medium comprising instructions executable by a processor to:
generate, from data collected by a first sensor within an area within which a mmWave sensor is to be utilized for presence detection, a model of the area;
refine, from data collected by a second sensor within the area, the model of the area; and
shape, based on the refined model, a detection field of view of the mmWave sensor to be contained within the area.

8. The non-transitory machine-readable storage medium of claim 7, wherein the model includes a sound map of the area and wherein the instructions to refine the model of the area include instructions to superimpose the data collected by the second sensor on the sound map of the area.

9. The non-transitory machine-readable storage medium of claim 8, wherein the second sensor includes a depth camera and wherein the data collected by the depth camera includes a distance to an object in the area.

10. The non-transitory machine-readable storage medium of claim 8, wherein the second sensor includes a red, green, blue (RGB) camera and wherein the data collected by the RGB camera is processed with an edge detection technique to identify edges in the area.

11. The non-transitory machine-readable storage medium of claim 7, wherein the instruction to shape the detection field of view of the mmWave sensor includes adjusting the detection field of view of the mmWave sensor to exclude presence detection data from outside of the area.

12. A method comprising:
generating, from data collected by a first sensor, a model of an area within which a mmWave sensor is to be utilized for presence detection;
modifying, based on the model, a detection field of view of the mmWave sensor to be contained within the area;
performing the presence detection within the area utilizing the shaped detection field of view of the mmWave sensor, and
adjusting a device in the area in response to detecting a presence within the area.

13. The method of claim 12, wherein modifying the detection field of view of the mmWave sensor includes adjusting a wave strength of an electromagnetic wave emitted from the mmWave sensor.

14. The method of claim 13, wherein adjusting the wave strength of the electromagnetic wave emitted from the mmWave sensor includes adjusting an amount of power provided to an antenna of the mmWave sensor.

15. The method of claim 12, wherein modifying the detection field of view of the mmWave sensor includes filtering out mmWave signal detections from outside of the area.
